(19) United States
(12) Patent Application Publication
(10) Pub. No.: US 2026/0349023 A1
(43) Pub. Date: Nov. 5, 2026

(54) STRAIGHT IN PERPENDICULAR BLINDMATE MODULE CONNECTOR, SLIDING WEDGE MECHANICS

(71) Applicant: Teradyne, Inc., North Reading, MA (US)

(72) Inventor: Steve E. Sanchez, Newbury Park, CA (US)

(73) Assignee: Teradyne, Inc., North Reading, MA (US)

(21) Appl. No.: 19/180,908

(22) Filed: Apr. 16, 2025

(51) Int. Cl. G01R 31/28; H01R 12/72

(52) U.S. Cl. CPC G01R 31/2834; H01R 12/722

(57) ABSTRACT

Perpendicular blind mate connection modules and automatic test equipment systems comprising the same are provided. Effective and reliable connection is provided through a connector having contacts facing a direction which is perpendicular to an insertion direction of the connector into an adapter. Some embodiments provide for detent features on the connector and/or the adapter.

### BACKGROUND

### Field

The present disclosure relates to a connection module for facilitating electrical connections such as may be used in automatic test equipment (ATE) systems.

### Related Art

ATE and other electrical systems may require signal pathways connecting components such as devices under test (DUTs) and device interface boards (DIBs). Connections may sometimes be desirable between components which are physically separated and include signal leads oriented perpendicularly to one another.

### BRIEF SUMMARY

According to an aspect of the technology, an automatic test equipment system is provided. The system comprises a DIB configured to support a DUT, an instrument, an adapter having a plurality of signal leads and configured to provide connection between the DIB and the instrument, and a connector. The connector comprises a mechanical insert and a signal path coupled to the mechanical insert and configured to transmit signals between the DUT and the instrument, the signal path comprising a plurality of contacts facing a first direction. The adapter is configured to receive the connector in a mating direction substantially perpendicular to the first direction. The connector is configured to slide into the adapter in a mating orientation in which the plurality of signal leads are configured to transmit signals to and/or receive signals from the plurality of contacts of the signal path in the first direction substantially perpendicular to the mating direction.

According to an aspect of the technology, a perpendicular blind mate connection module for ATE is provided. The connection module comprises a connector and a DIB. The connector comprises a mechanical insert, a PCB fixed to the mechanical insert and having a plurality of exposed contact pads on a first side facing a first direction and a plurality of cables coupled to a second side of the PCB. The DIB comprises an adapter configured to receive the connector in a mating direction substantially perpendicular to the first direction and a plurality of conductive leads. The connector is configured to slide into the adapter in a mating orientation in which the plurality of conductive leads of the DIB are configured to make electrical contact with the plurality of exposed contact pads on the first side of the PCB in the first direction substantially perpendicular to the mating direction.

According to an aspect of the technology, a connector for a perpendicular blind mate connection module for ATE is provided. The connector comprises a mechanical insert, a PCB fixed to the mechanical insert and having a plurality of exposed contact pads on a first side facing a first direction, and a plurality of cables coupled to a second side of the PCB. The connector is configured to be inserted in a mating direction into an adapter of a DIB in a mating orientation such that the plurality of exposed contact pads of the PCB make electrical contact with a plurality of conductive leads of the DIB in the first direction. The mating direction is substantially perpendicular to the first direction.

According to an aspect of the technology, a DIB for a perpendicular blind mate connection module for ATE is provided. The DIB comprises an adapter configured to receive a connector in a mating direction and a plurality of conductive leads facing a first direction. The adapter is configured to receive the connector in a mating orientation in which the plurality of conductive leads are configured to make electrical contact with a plurality of exposed contact pads of the connector in the first direction. The mating direction is substantially perpendicular to the first direction.

According to an aspect of the technology, a method of establishing a perpendicular blind mate connection is provided. The method comprises inserting a connector comprising a plurality of cables coupled to a PCB into an adapter of a DIB in a mating direction and making electrical contact between a plurality of exposed contact pads of the PCB with a plurality of conductive leads of the DIB in a contact direction which is substantially perpendicular to the mating direction.

### BRIEF DESCRIPTION OF DRAWINGS

Various aspects and embodiments of the technology will be described with reference to the following figures. It should be appreciated that the figures are not necessarily drawn to scale. Items appearing in multiple figures are indicated by the same reference number in all the figures in which they appear.

FIG. 1 is a block diagram of an ATE system including a perpendicular blind mate connector, according to some embodiments of the present disclosure.

FIG. 2A is a perspective view of a connector and a DIB configured for perpendicular blind mate connection but pictured in an unmated state, according to some embodiments of the present disclosure.

FIG. 2B is a view from the perspective of FIG. 2A of the connector and the DIB, mated, according to some embodiments of the present disclosure.

FIG. 3A is a further perspective view of the connector and the DIB of FIG. 2A, unmated and showing an insertion direction, according to some embodiments of the present disclosure.

FIG. 3B is a view from the perspective of FIG. 3A of the connector and the DIB, mated, according to some embodiments of the present disclosure.

FIGS. 4A-4G are perspective views of the DIB of FIG. 2A, according to some embodiments of the present disclosure.

FIGS. 5A-5G are perspective views of the connector of FIG. 2A, according to some embodiments of the present disclosure.

FIG. 6A is a perspective view of the connector and the DIB of FIG. 2A, mated, according to some embodiments of the present disclosure.

FIG. 6B is a cross-sectional view in the x-z plane at a line marked “6B” in FIG. 6A of the connector and the DIB, mated and showing a contact direction, according to some embodiments of the present disclosure.

FIG. 7 is a cross-sectional view of a connector and a DIB each provided with a detent feature, according to some embodiments of the present disclosure.

FIG. 8 is a flow chart illustrating a method of establishing a perpendicular blind mate connection, according to some embodiments of the present disclosure.

FIG. 9 is a perspective view of an ATE system including a connector having a visible signal path and a partially exploded DIB having a DUT, according to some embodiments of the present disclosure.

### DETAILED DESCRIPTION

Aspects of the present technology provide connection between automatic test equipment (ATE) system components. For example, connection may be provided between instruments and device interface boards (DIBs) on which a device under test (DUT) is disposed. The testing of modern electrical systems, such as semiconductor chips, may be performed by ATE systems having one or more instruments that connect to a DUT via a DIB. Signals may be transmitted between the ATE system instrument and the DUT, passing through the DIB. Connection between the instrument and the DIB may be made by a connector arrangement including a connector and an adapter each having signal leads.

Commonly, DIBs are loaded into an ATE system end-on. Such a mounting configuration may be space-efficient, allowing multiple DIBs to be loaded into the ATE system to allow multiple DUTs to be tested by the ATE. Electrical connection between signal leads on the DIB and signal leads on the connector involves navigating a 90-degree change in direction compared to the end-on mounting direction of the DIB in the ATE system.

Aspects of the present technology provide a perpendicular blind mate connection module which provides effective and reliable connection through a connector having a plurality of contacts facing a first direction, which connector may be inserted into an adapter of a DIB in a second direction such that the plurality of contacts may receive and/or transmit signals from a plurality of signal leads of the DIB. Aspects disclosed herein include systems, devices, and methods relating to establishing such a perpendicular connection and may be applicable to ATE systems, as one example. In some embodiments, detent features retain the inserted connector in the adapter.

In some systems, connection between components may be “blind,” meaning that, because a component's mating orientation obscures view of a point of contact between signal leads, a user is unable to see whether a connection is made as desired when the component is in the mating orientation. Absent visible confirmation that effective contact is made, it may be desirable for connectors used in blind connections to have features which ensure proper alignment and contact between signal leads when the connector is in the mating orientation.

Further description of aspects and embodiments of the creation and operation of a perpendicular blind made connection module is provided below. It should be appreciated that various aspects described herein may be implemented in any of numerous ways. Examples of specific implementations are provided herein for illustrative purposes only. In addition, the various aspects and embodiments below may be used alone or in any combination and are not limited to the combinations explicitly described herein.

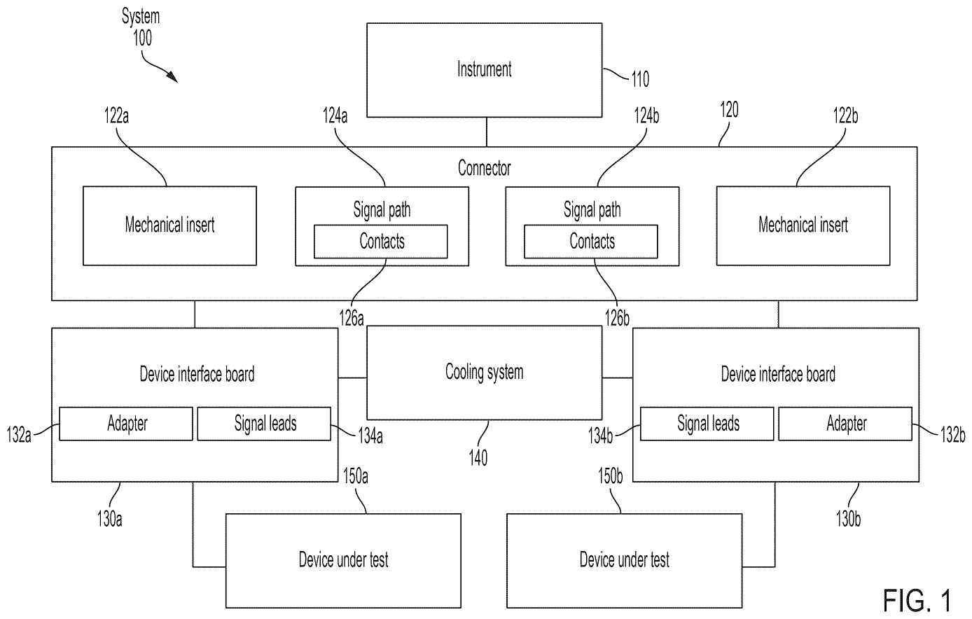

FIG. 1 is a block diagram of an ATE system 100 including a perpendicular blind mate connector 120, according to some embodiments of the present disclosure. The system 100 includes an instrument 110, the connector 120, two DIBs 130a and 130b, a cooling system 140, and two DUTs 150a and 150b.

The instrument 110 may be configured to send and receive signals used to test, and potentially diagnose faults within, components such as DUTs 150a and 150b. The instrument 110 may be configured to store results of testing in memory. In some embodiments, the instrument 110 may include and/or may be coupled to a display configured to output the results of testing to a user. In some embodiments, the instrument 110 may cause action as a result of a test, such as to sort the DUT based on the result or to initiate testing of a subsequent DUT.

The instrument 110 may include circuitry configured to process any number of digital and/or analog signals. For example, the instrument 110 may include digital and/or analog multimeters. The instrument 110 may be configured to test any suitable aspect of a DUT 150, including logic, radio frequency (RF), analog, power, mixed-signal, and memory technologies. The instrument 110 may include a plurality of signal leads which—indirectly through a connector 120 or in some embodiments, directly—connect the instrument 110 to the DUT 150.

The connector 120 may include a mechanical insert 122, a signal path 124, and a plurality of contacts 126. In some embodiments, the connector 120 may include two mechanical inserts 122a and 122b, two signal paths 124a and 124b, and two pluralities of contacts 126a and 126b. However, aspects of the disclosed technology are not limited to one or two mechanical inserts 122, signal paths 124, and pluralities of contacts 126, and there may be connectors which have a greater number of these components depending on the configuration of a system in which the connector is integrated. In some embodiments, the number of mechanical inserts 122, signal paths 124, and pluralities of contacts 126 may correspond to the number of DIBs 130 coupled to the connector 120 and/or the number of DUTs 150 coupled to each DIB 130. In some embodiments, the connector 120 has more signal paths 124 than mechanical inserts 122; there may alternatively or additionally be systems in which the number of mechanical inserts 122 and/or the number of signal paths 124 exceed the number of DIBs 130 without departing from the scope of this disclosure.

The connector 120 may serve to connect the instrument 110 to a DIB 130 by way of the signal path 124. For example, the signal path 124 may couple at one end to the instrument 110, and at another end terminate at the plurality of contacts 126 which are configured to couple with signal leads 134 of the DIB 130. The signal path 124 may be configured to carry signals relating to voltages, radio frequencies, optical transmissions, laser diodes, and/or any suitable signals which are or may be used in the system 100. The signals may be static or dynamic, and the signal path 124 may facilitate both active and passive signal delivery. The signal path 124 may include cables, a straight flex circuit, a PCB, an RF connector, and/or a combined signal deliver and thermal cooling system.

The connector 120 may be configured to mechanically couple to the DIB 130 such that the plurality of contacts 126 of the connector 120 couple to a plurality of signal leads 134 of the DIB 130. In some embodiments, the mechanical insert 122 of the connector 120 may be configured to be received in an insertion direction by an adapter 132 of the DIB 130. The contacts 126 and the signal leads 134 may be positioned such that they establish a connection suitable for signal transmission when the adapter 132 receives the mechanical insert 122. For example, the contacts 126 and the signal leads 134 may establish an electrical connection with one another. The contacts 126 may face a direction which is substantially perpendicular to the insertion direction. Additionally, while reference is made herein to “pluralities” of contacts 126 and signal leads 134, there may be embodiments of the present technology in which there is effectively only a single contact 126 and signal lead 134 configured to transmit one or more signals, for example through time-division multiplexing.

The mechanical insert 122 and the adapter 132 may be shaped complementarily to one another such that the mechanical insert 122 slides into the adapter 132. In some embodiments, the mechanical insert 122 may have a wedge, or other suitable feature, such that pressing the mechanical insert 122 into the adapter 132 in the insertion direction has the effect of producing a force between the contacts 126 and the signal leads 134 to facilitate connection therebetween. In some embodiments, the mechanical insert 122 and/or the adapter 132 may include a detent feature—for example, a locking feature—such that the mechanical insert 122 may be locked into a mating orientation when fully inserted into the adapter 132.

In some embodiments, the system components to which the mechanical insert 122 of the connector 120 and the adapter 132 are connected may be varied from the configuration shown. For example, while in the figures the adapter 132 is connected to the DIB 130 and the signal path 124 of the connector 120 is connected to the instrument 110, in some embodiments the adapter 132 may be connected to the instrument 110 and the signal path 124 of the connector 120 may be connected to the DIB 130.

The DIB 130 may include a printed circuit board (PCB) on which a DUT 150 may be disposed during operation of the system 100. The adapter 132 of the DIB 130 may be fastened to the PCB. The signal leads 134 may be coupled to traces within and/or on the surface of the PCB which are further coupled to the DUT 150. The DIB 130 may support one or more DUTs 150.

In operation, the DIB 130 may generate heat, for example as a result of electrical current flowing within the DIB 130. However, increased temperatures—as well as change in temperature in general—may adversely impact signals propagated through the DIB, which may in turn reduce the accuracy of data collected by the instrument 110 and worsen the performance of the system 100. In extreme cases, unmitigated temperature increases could cause permanent damage to components of the system 100. Thus, it may be advantageous to cool the DIB 130.

The cooling system 140 may be configured to cool the DIB 130. The cooling system 140 may be any suitable cooling system 140 for dissipating heat generated by the DIB 130 and for maintaining the DIB 130 at or near a target temperature. For example, the cooling system 140 may operate by conduction and/or convection. In some embodiments, the cooling system 140 may be a water-cooled system.

In embodiments having multiple DIBs 130, the cooling system 140 may be disposed between adjacent DIBs 130 to increase space and energy efficiency of the cooling system 140. A person of ordinary skill in the art will recognize how to select a suitable configuration of cooling system 140 for a contemplated system 100 based on the number of DIBs 130, relative position of DIBs 130, desired cooling, and so forth.

The DUT 150 may be removably coupled to the DIB 130. DUT 150 may be any suitable assembly or component undergoing testing by the system 100. In some embodiments, there may be more than one DUT 150 associated with a given DIB 130.

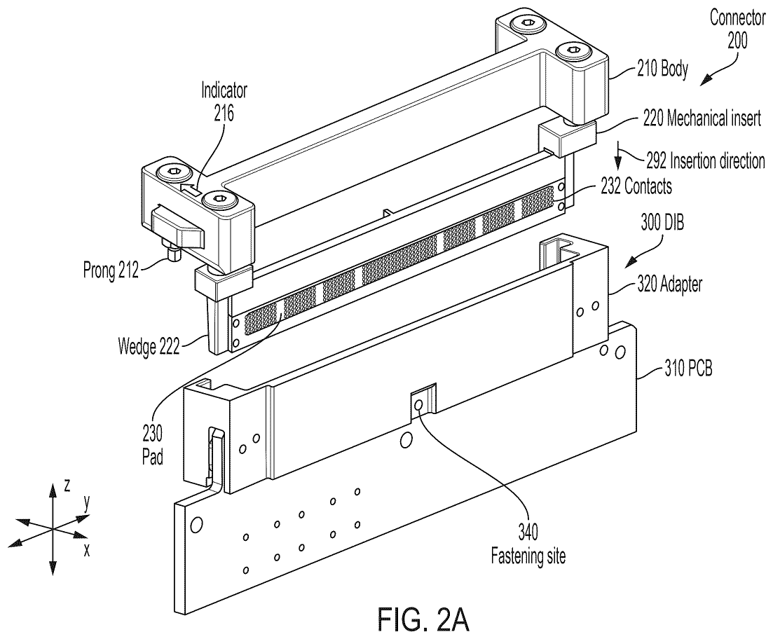

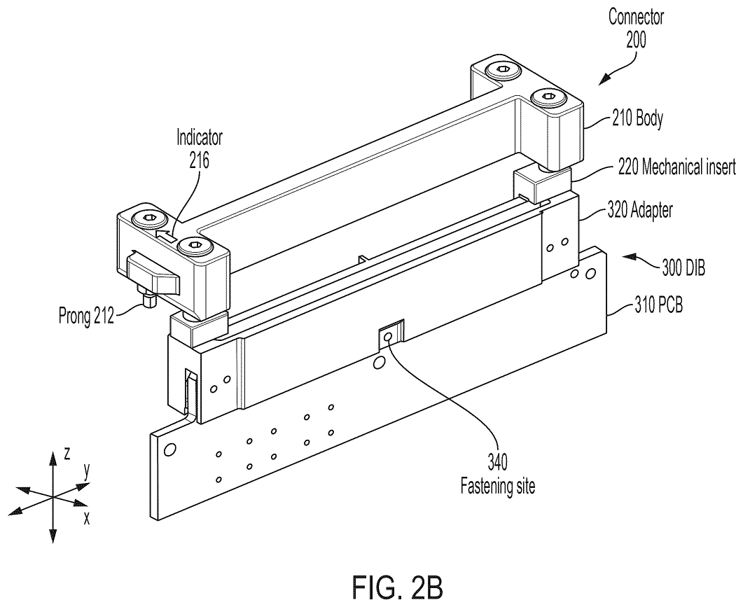

FIGS. 2A-6C show a connector 200 and a DIB 300 representing a non-limiting implementation of a perpendicular blind mate connection module such as may be used in the ATE system 100 described above. Thus, while the components of the connector 200 and the DIB 300 may have the properties of the corresponding components of the connector 120 and the DIB 130 described above, aspects of the perpendicular blind mate connection module disclosed herein are not confined to, limited to, or exclusively implementable in the embodiment shown in FIGS. 2A-6C. For clarity, components are not necessarily labelled in all the figures in which they appear.

An x-y-z coordinate system indicator is provided in conjunction with the following figures for convenience of explanation. Each axis is orthogonal to the other two axes. The coordinate system indicator is consistent across the figures and may thus be used to orient a viewer as to a perspective shown in a particular figure. For each axis, the label—that is, the character “x,” “y,” or “z”—appears on the “positive” side of the axis. As is conventional, in figures where the plane of the drawing is parallel to a plane of the coordinate system, a small circle at the center of the coordinate system indicator contains a dot if the axis orthogonal to the plane of the drawing is positive “out of the page” or an X if the axis orthogonal to the plane of the drawing is positive “into the page.”

FIG. 2A is a perspective view of a connector 200 and a DIB 300 configured for perpendicular blind mate connection but pictured in an unmated state. As can be seen, an insertion direction 292—or mating direction—is in the “z” direction in the coordinate system of the figure. That is, relative movement of the connector 200 and/or the DIB 300 towards one another along the z-axis may cause the connector 200 to slide into the DIB 300. FIG. 2B is a view from the perspective of FIG. 2A of the connector 200 and the DIB 300, mated. As can be seen, the DIB 300 is receiving the connector 200.

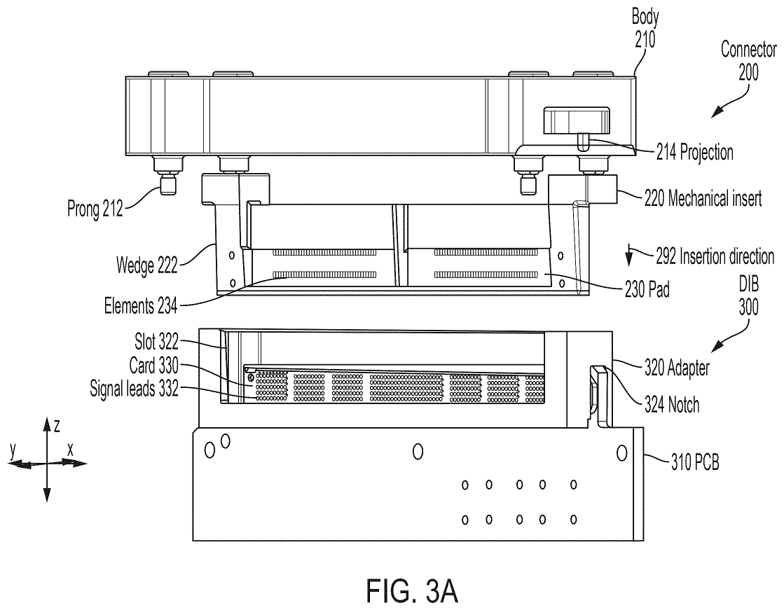

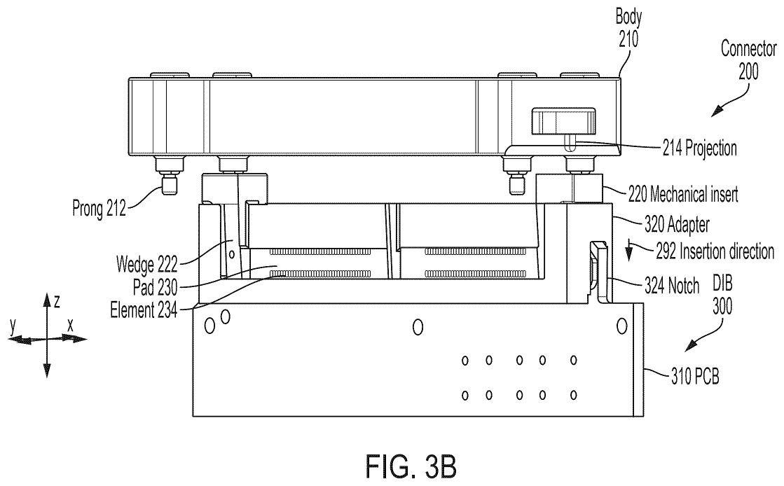

FIG. 3A is a further perspective view of the connector 200 and the DIB 300, unmated and showing an insertion direction 292. FIG. 3B is a view from the perspective of FIG. 3A of the connector and the DIB, mated. FIGS. 3A and 3B provide an alternative perspective of the connector 200 and DIB 300 pre-insertion and post-insertion, akin to FIGS. 2A and 2B, respectively.

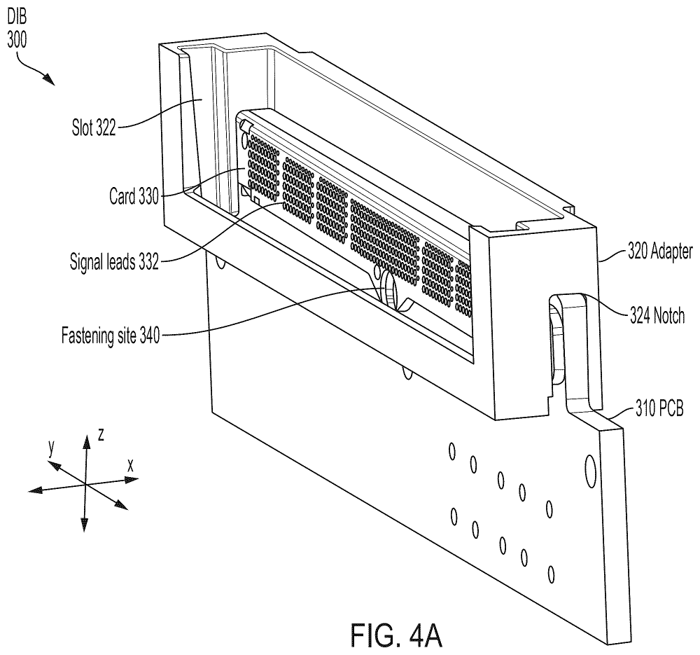

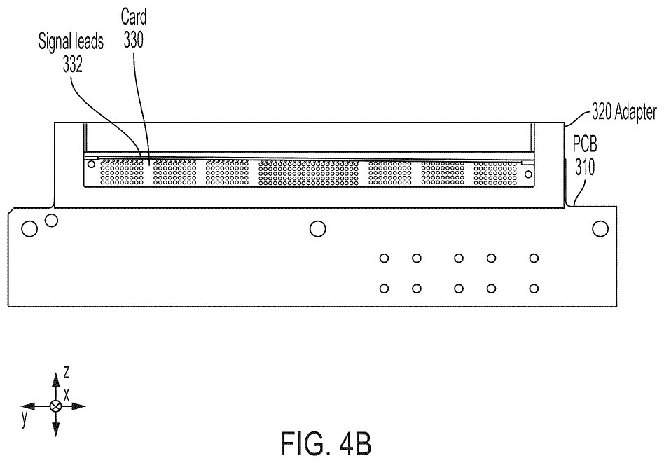

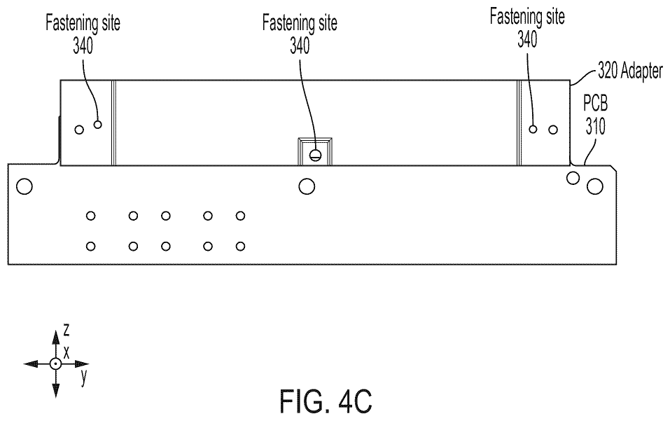

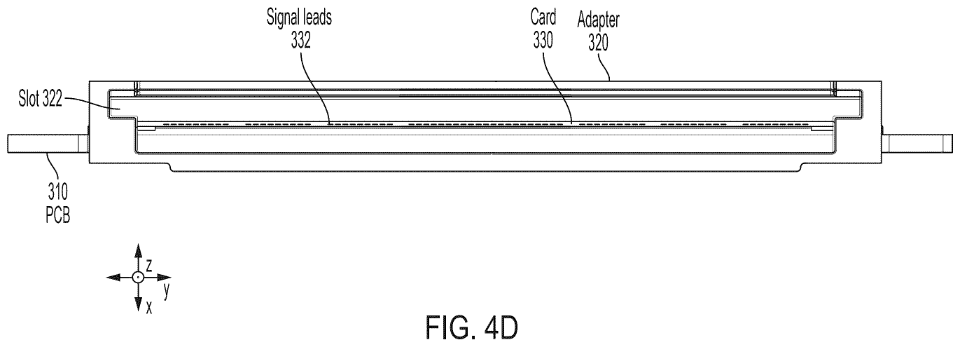

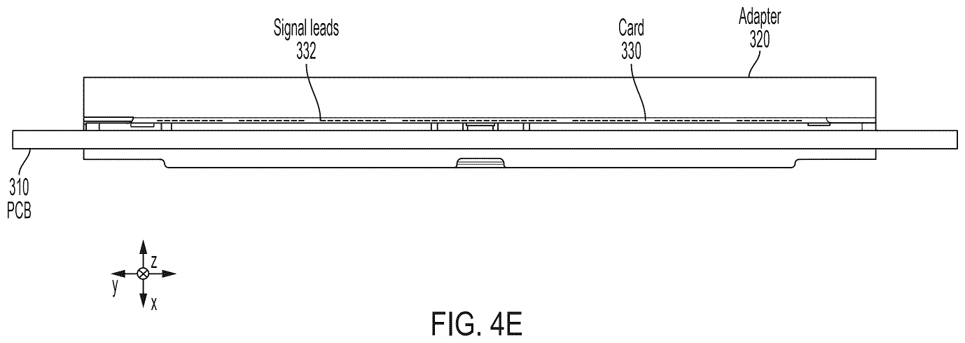

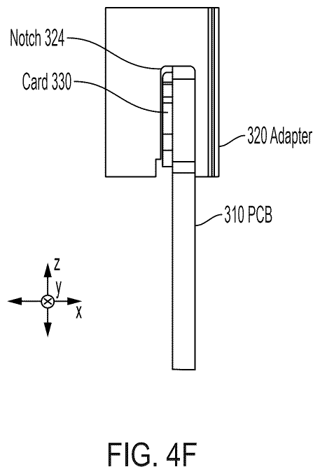

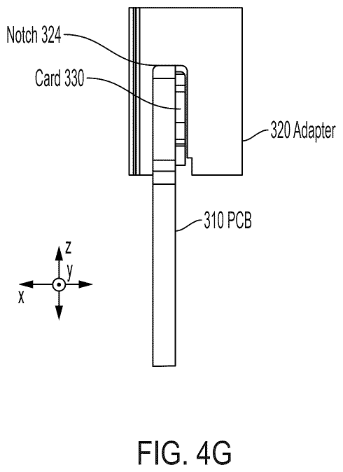

FIGS. 4A-4G are perspective views of the DIB 300. As can be seen, the DIB 300 includes a PCB 310, an adapter 320 having a slot 322 and a notch 324, a card 330 having signal leads 332, and a fastening site 340.

The PCB 310 may have a DUT (not shown) disposed on a body region thereof. The PCB 310 and the DUT may be operatively coupled such that signals from an instrument (not shown) pass through the PCB 310 to the DUT.

The PCB 310 may include, extending from the body region, a portion on which the card 330 may be disposed and which is received by the adapter 320.

The PCB 310 may be of any suitable construction for use in a system in which the DIB 300 is integrated. For example, the PCB may have any suitable number of layers, traces, pads, and vias of any suitable material and design.

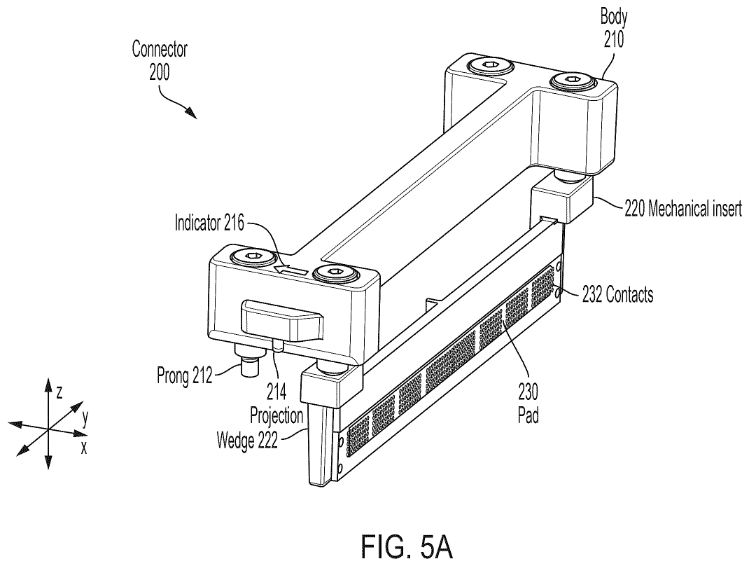

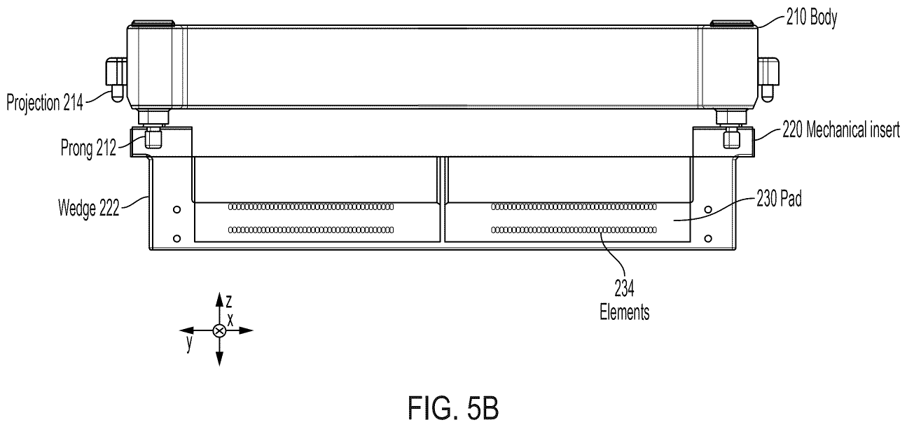

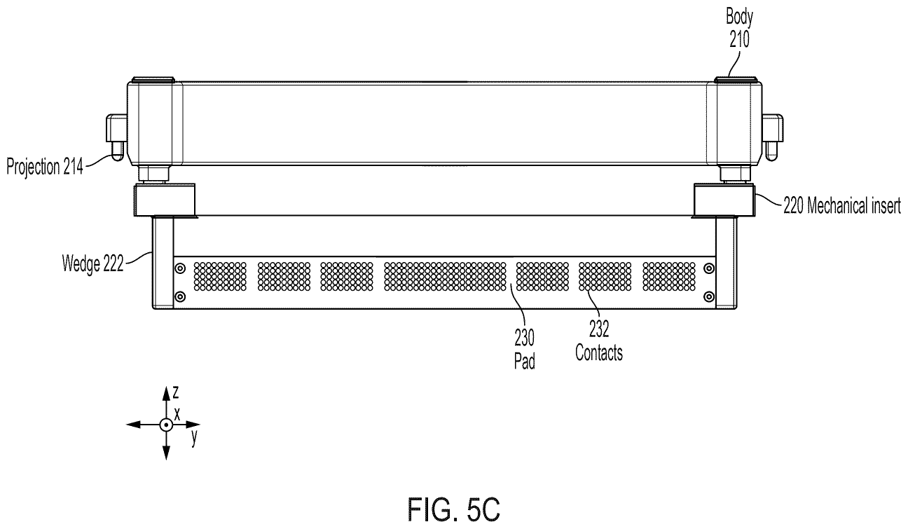

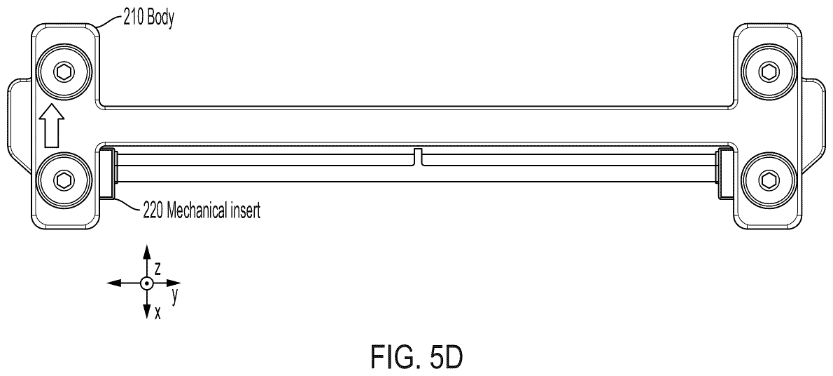

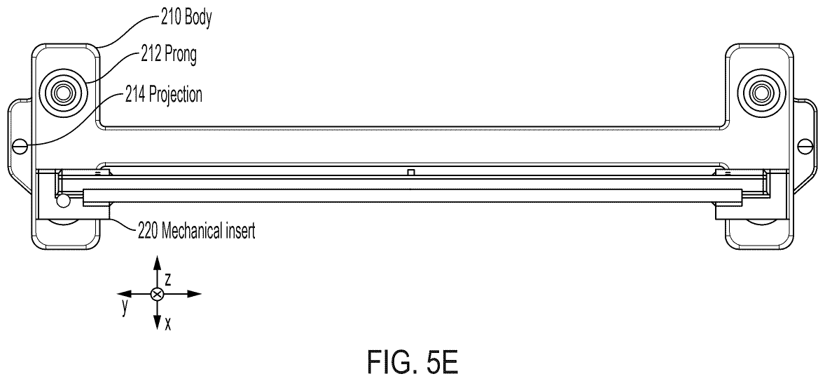

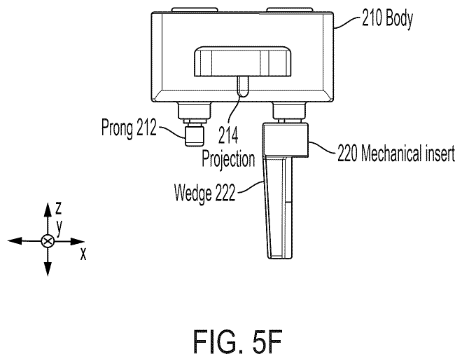

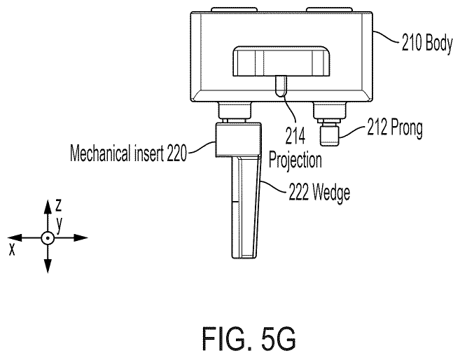

The adapter 320 includes a slot 322 configured to receive a wedge 222 of a mechanical insert 220 (FIGS. 5A-5G) of the connector. The slot 322 is shaped complementarily to the wedge 222 such that the slot 322 is narrower “deeper”—that is, in the negative z-direction of the figures—in the slot than at the opening of the slot 322 which first receives the wedge 222. While the slot 322 shown becomes linearly narrower, aspects of the technology disclosed herein are not limited in this way, and the slot 322 may have any shape suitable for receiving a complementary portion of the mechanical insert 220.

The slot 322 may be seen at both ends of the adapter 320. Configuring the slot 322 in this way—for example, allowing a portion of the mechanical insert 220 to fill a region of the slot 322 at two ends of the adapter 320—may prevent the mechanical insert 220 from inadvertently pivoting away from the adapter 320 and thus decoupling the contacts 232 from the signal leads 332.

The adapter 320 includes a notch 324 configured to receive the portion of the PCB 310 on which the card 330 is disposed such that the signal leads 332 are configured to couple with contacts 232 (FIGS. 5A-5G) of the connector 200 when the connector 200 is mated with the DIB 300.

The adapter 320 may be formed of any suitable material. The adapter 320 may be integrally formed or may be an assembly of multiple components. The adapter 320 may include conductive and/or non-conductive materials. In some embodiments, the adapter 320 may be formed of a plastic. The material and/or materials of which the adapter 320 is formed may be selected based on their mechanical, electrical, and or thermal performance as well as their cost.

The card 330, which may be considered an interposer, is affixed to the PCB 310 such that connections are made between the signal leads 332 of the card 330 and traces within the PCB 310. In some embodiments, the card 330 may be integrally formed with the PCB 310. In other embodiments, the card 330 may be removably or irremovably fastened to the PCB 310 such as by mechanical means such as screws and/or chemical means such as epoxy. The card 330 may be of any suitable construction for coupling to the PCB 310 as desired for performance of the DIB 300.

The signal leads 332 of the card 330 may be any material suitable to transmit signals between the contacts 232 and the PCB 310. For example, the signal leads may be copper. However, there may be some embodiments in which signals transmitted are optical signals such that the materials of the signal leads 332—as well as of other components such as contacts 232, traces within the PCB 310, and a signal path of the connector 200, for example—may be chosen based on optical properties rather than or in addition to electrical properties. In some embodiments, the signal leads 332 may include a plurality of pins.

The fastening site 340 passes through the PCB 310, the adapter 320, and the card 330 to allow the installation of a fastener—for example, a screw—to retain the components of the DIB 300 in alignment. To further secure the components and to prevent rotation, there may be additional fastening sites 340 such as shown in FIG. 4C. There may be fastening sites 340 which do not combine all of the PCB 310, the adapter 320, and the card 330 but instead fasten only the PCB 310 to the card 330, the PCB 310 to the adapter 320, or the adapter 320 to the card 330. Any suitable number and design of fastening sites 340 may be used to reliably secure the assembly of the DIB 300 as desired.

FIGS. 5A-5G are perspective views of the connector 200, according to some embodiments of the present disclosure. As can be seen, the connector 200 includes a body 210 having prongs 212, projections 214, and an indicator 216, a mechanical insert 220 having a wedge 222, and a pad 230 having contacts 232 and elements 234.

The body 210 may couple to the mechanical insert 220 via one or more prongs 212 which insert into respective cavities (not shown) of the mechanical insert 220. As shown, the body 210 may be provided with sufficient prongs 212 such that the body 210 may couple to more than one mechanical insert 220. In some embodiments, the body 210, the prongs 212, and/or the mechanical insert 220 may be configured such that, when the mechanical insert 220 is inserted into the adapter 320, a force acts to maintain a connection between contacts 232 of the pad 230 and signal leads 332 of the card 330. In some embodiments, this force may comprise one or more spring forces and one or more normal forces.

While prongs 212 are provided as an example mechanism by which the body 210 may couple with the mechanical insert 220, it is understood that any suitable means or mechanism may be used to couple the mechanical insert 220 to the body 210. In some embodiments, the body 210 may be integrally formed with the mechanical insert 220, for example such that no discrete coupling means is required.

The body 210 may also include one or more projections 214. The projections 214 may be used to align and/or couple the body 210 with other components of a system in which the connector 200 is integrated.

The body 210 may be provided with one or more indicators 216. The indicator 216 may serve to inform a user installing the connector 200 as to the proper orientation of the connector 200 such that, for example in an embodiment wherein a connector 200 includes multiple mechanical inserts 220, appropriate coupling is made between respective mechanical inserts 220 and receiving adapters 320.

The mechanical insert 220 may be configured to be received by a corresponding adapter 320 when the connector 200 mates to one or more DIBs 300. For example, as shown in FIGS. 2A-3B, the mechanical insert 220 may slide in the z-direction into the adapter 320, thereby coupling the connector 200 to the DIB 300.

The mechanical insert 220 may include a wedge 222 which is configured such that, when the mechanical insert 220 is mated to the adapter 320, a force perpendicular to an insertion direction of the connector 200 is applied between the mechanical insert 220 and the adapter 320.

The pad 230 may be disposed on and/or coupled to the mechanical insert 220. For example, the pad 230 may be fixed to the mechanical insert 220 by one or more mechanical fasteners and/or by one or more adhesives.

The pad 230 may be, for example, a printed circuit board of any suitable construction for use in a system in which the connector 200 is integrated. For example, the pad 230 may have any suitable number of layers, traces, pads, and vias of any suitable material and design.

The pad 230 may include an array of contacts 232 which are configured to mate with signal leads 332 of a card 330 of the mating DIB 300. For example, the contacts 232 may have a number, layout, and orientation corresponding and/or complementary to the number, layout, and orientation of the signal leads 332 of the card 330.

Significantly, the contacts 232 may face, when the connector 200 is in a mating orientation, a direction (e.g., positive “x” direction in the coordinate system of the figures) which is perpendicular to the insertion direction (along the “z” axis in the coordinate system of the figures) and parallel and opposite to a direction (negative “x” direction in the coordinate system of the figures) which the signal leads 332 face. Accordingly, when the connector 200 is inserted into the DIB 300, the wedge 222 may cause the contacts 232 to operatively connect with the signal leads 332.

The pad 230 may also include an array of elements 234 which are configured to operatively connect to one or more signal paths of the connector. For example, the signal path may include a plurality of wires which are soldered at one end to the elements 234 and which operatively connect at another end to, for example, an instrument of an ATE system.

The contacts 232 may be disposed on an opposite face of the pad 230 from the elements 234. In some embodiments, the number of elements 234 may correspond to—for example, be equal to—the number of contacts 232. For example, respective elements 234 may be connected—for example, by traces internal to the pad 230—to corresponding contacts 232. In some embodiments, there may be greater or fewer elements 234 than contacts 232, and a plurality of elements 234 may be connected to a single contact 232 and/or a single element 234 may be connected to a plurality of contacts 232.

The contacts 232 and the elements 234 of the pad 230 may be any suitable material to transmit signals used by the system in which the contacts 232 and the elements 234 are integrated, for example as was described in conjunction with the signal leads 332 of the card 330 of the DIB 300.

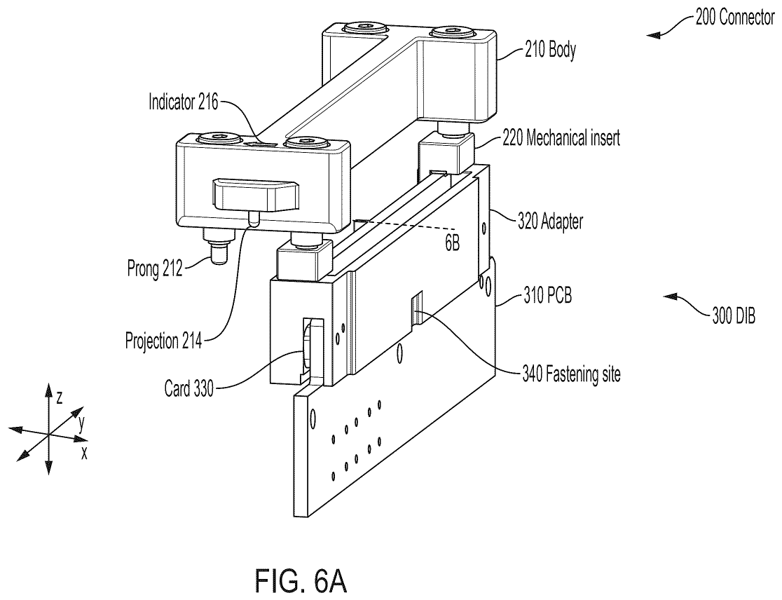

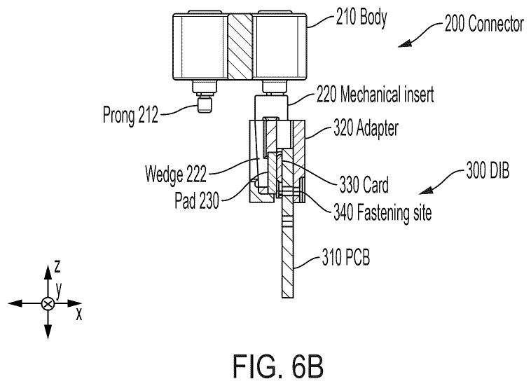

FIG. 6A is a perspective view of the connector 200 and the DIB 300, mated, according to some embodiments of the present disclosure.

FIG. 6B is a cross-sectional view in the x-z plane at a line marked “6B” in FIG. 6A of the connector 200 and the DIB 300, mated and showing a contact direction, according to some embodiments of the present disclosure. As was described and as can be seen, the mating, or insertion, direction of the connector 200 and the DIB 300 is in the z-direction, whereas a connection direction between the contacts 232 of pad 230 and the signal leads 332 of the card 330 is in the x-direction.

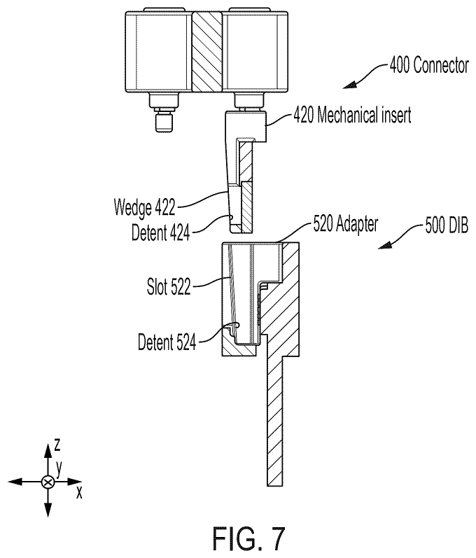

FIG. 7 is a cross-sectional view of a connector 400 and a DIB 500 each provided with a detent feature 424 and 524, respectively, according to some embodiments of the present disclosure. Connector 400 may have the qualities and components of connector 200 described herein, and DIB 500 may have the qualities and components of DIB 300 described herein; for avoidance of needless repetition, only the detent features 424 and 524 are emphasized in conjunction with this figure.

As can be seen, a mechanical insert 420 of the connector 400 may be provided with a detent feature 424, for example disposed on the wedge 422. Alternatively, or additionally, an adapter 520 of the DIB 500 may be provided with a detent feature 524, for example disposed in the slot 522. The detent feature 424 of the connector 400 may be configured to mate with the detent feature 524 of the DIB 500 to align and/or retain the mechanical insert 420 in the adapter 520 when the connector 400 and the DIB 500 are mated. While as shown the detent feature 424 is configured to receive the detent feature 524, this is merely an example, as various other configurations are possible. Any suitable combination of detent features may be used to retain and/or align the mechanical insert 420 in the adapter 520 as desired.

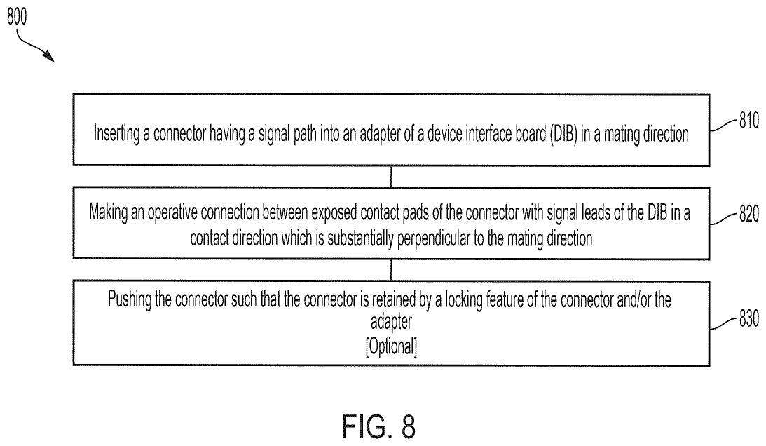

FIG. 8 is a flow chart illustrating a method 800 of establishing a perpendicular blind mate connection, according to some embodiments of the present disclosure. The method 800 may be performed with components such as the connector 200 and DIB 300 described herein, but it is not limited thereto.

As shown, the method 800 for establishing a perpendicular blind mate connection includes, in some embodiments, a first step 810 of inserting a connector having a signal path into an adapter of a DIB in a mating direction.

The method 800 further includes, in some embodiments, a second step 820 of making an operative connection between exposed contact pads of the connector and signal leads of the DIB in a contact direction which is substantially perpendicular to the mating direction.

The method 800 further includes, optionally and in some embodiments, a third step 830 of pushing the connector such that the connector is retained by a locking feature of the connector and/or the adapter.

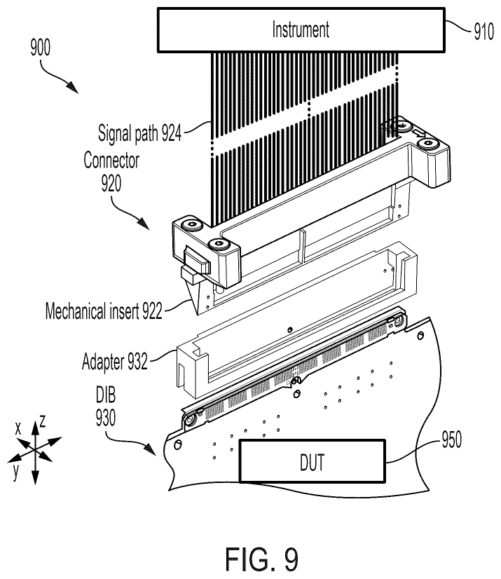

FIG. 9 is a perspective view of an ATE system 900 including a connector 920 having a visible signal path 924 and a partially exploded DIB 930 having a DUT 950, according to some embodiments of the present disclosure. For the avoidance of redundant description, it is understood that the ATE system 900 may have the properties of ATE system 100, that the connector 920 may have the properties of connector 200 and/or connector 400, that the DIB 930 may have the properties of DIB 300 and/or DIB 500, and that the DUT 950 may have the properties of DUT 150 or any other suitable DUT for use in an ATE system.

As shown, the connector 920 of the ATE system 900 includes a signal path 924 which in this example includes a plurality of cables or wires. Each cable of the signal path 924 may be soldered, or otherwise operatively connected, to a respective element of a pad of the mechanical insert 922 of the connector 920. Further, each cable of the signal path 924 may be soldered, or otherwise operatively connected, to an instrument 910. The instrument 910 may transmit signals to and/or receive signals from the DUT 950 disposed on the DIB 930 via the signal path 924.

Because the DIB 930 is shown partially exploded, the adapter 932 may be seen in a state in which it is not fastened to a PCB of the DIB 930 fitted into a notch of the adapter 932.

The choice of ATE system components shown in the figures, and the configuration thereof, are provided as non-limiting examples. For example, while as shown in the figures a signal path directly couples a connector to an instrument, in other embodiments there may be any number of intervening components between the connector and the instrument. As a further example, the signal path may directly couple the connector to a DIB rather than the instrument, and the connector may be inserted into an adapter provided on the instrument rather than the DIB. By way of convenient explanation with reference to the illustration in FIG. 9, the instrument 910 may be in the stead of the DIB 930 and the DUT 950 and the DIB 930 and the DUT 950 may be in the stead of the instrument 910. Likewise, DIB 300 and/or DIB 500 may be an instrument without departing from the scope of this disclosure. Those skilled in the art will readily appreciate that the aspects and embodiments described herein are capable of application in any suitable electrical system.

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Use of ordinal terms such as “first,” “second,” “third,” et cetera, does not by itself connote any priority, precedence, or order of one element over another or the temporal order in which acts of a method are performed. Such terms are used merely as labels to distinguish one element having a certain name from another element having a same name (but for use of the ordinal term) to distinguish the elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An automatic test equipment system, comprising:
a device interface board (DIB) configured to support a device under test (DUT);
an instrument;
an adapter having a plurality of signal leads and configured to provide connection between the DIB and the instrument; and
a connector, comprising:
a mechanical insert; and
a signal path coupled to the mechanical insert and configured to transmit signals between the DUT and the instrument, the signal path comprising a plurality of contacts facing a first direction,
wherein:
the adapter is configured to receive the connector in a mating direction substantially perpendicular to the first direction, and
the connector is configured to slide into the adapter in a mating orientation in which the plurality of signal leads are configured to transmit signals to and/or receive signals from the plurality of contacts of the signal path in the first direction substantially perpendicular to the mating direction.

2. The automatic test equipment system of claim 1, further comprising a cooling system disposed adjacent to the DIB.

3. The automatic test equipment system of claim 1, wherein:
the adapter is connected to the DIB and the signal path of the connector is connected to the instrument; or
the adapter is connected to the instrument and the signal path of the connector is connected to the DIB.

4. The automatic test equipment system of claim 1, wherein the signal path is configured to carry one or more of: static signals, dynamic signals, voltage signals, optical signals, radio frequency signals, and laser diode signals.

5. The automatic test equipment system of claim 1, wherein the signal path comprises one or more of cables, a straight flex circuit, a printed circuit board (PCB), a radio frequency (RF) connector, or combined signal delivery and thermal cooling system.

6. A perpendicular blind mate connection module for automatic test equipment (ATE), comprising:
a connector, comprising:
a mechanical insert;
a printed circuit board (PCB) fixed to the mechanical insert and having a plurality of exposed contact pads on a first side facing a first direction; and
a plurality of cables coupled to a second side of the PCB; and
a device interface board (DIB), comprising:
an adapter configured to receive the connector in a mating direction substantially perpendicular to the first direction; and
a plurality of conductive leads,
wherein the connector is configured to slide into the adapter in a mating orientation in which the plurality of conductive leads of the DIB are configured to make electrical contact with the plurality of exposed contact pads on the first side of the PCB in the first direction substantially perpendicular to the mating direction.

7. The perpendicular blind mate connection module of claim 6, wherein the mechanical insert is shaped to apply a force between the plurality of exposed contact pads and the plurality of conductive leads when the connector slides into the adapter.

8. The perpendicular blind mate connection module of claim 7, wherein the mechanical insert is shaped as a wedge.

9. The perpendicular blind mate connection module of claim 6, wherein the plurality of cables are electrically connected to the plurality of exposed contact pads via a plurality of soldered connections.

10. The perpendicular blind mate connection module of claim 6, wherein the DIB further comprises an interposer, and wherein the plurality of conductive leads are disposed on the interposer.

11. The perpendicular blind mate connection module of claim 10, wherein the plurality of conductive leads comprise a plurality of pins.

12. The perpendicular blind mate connection module of claim 6, wherein the connector and the adapter comprise complementary features configured to align the connector in the mating orientation.

13. The perpendicular blind mate connection module of claim 12, wherein the complementary features are further configured to lock the connector in the mating orientation.

14. The perpendicular blind mate connection module of claim 6, wherein the mating direction is substantially parallel to a surface of the DIB.

15. A connector for a perpendicular blind mate connection module for automatic test equipment (ATE), comprising:
a mechanical insert;
a printed circuit board (PCB) fixed to the mechanical insert and having a plurality of exposed contact pads on a first side facing a first direction; and
a plurality of cables coupled to a second side of the PCB,
wherein the connector is configured to be inserted in a mating direction into an adapter of a device interface board (DIB) in a mating orientation such that the plurality of exposed contact pads of the PCB make electrical contact with a plurality of conductive leads of the DIB in the first direction, and
wherein the mating direction is substantially perpendicular to the first direction.

16. The connector of claim 15, further comprising a locking feature configured to lock the connector in the mating orientation.

17. The connector of claim 15, wherein the mechanical insert is shaped to apply a force between the plurality of exposed contact pads and a plurality of conductive leads of the DIB when the connector is in the mating orientation.

18. The connector of claim 15, wherein the plurality of cables are electrically connected to the plurality of exposed contact pads via a plurality of soldered connections.

19. A device interface board (DIB) for a perpendicular blind mate connection module for automatic test equipment (ATE), comprising:
an adapter configured to receive a connector in a mating direction; and
a plurality of conductive leads facing a first direction,
wherein the adapter is configured to receive the connector in a mating orientation in which the plurality of conductive leads are configured to make electrical contact with a plurality of exposed contact pads of the connector in the first direction.
wherein the mating direction is substantially perpendicular to the first direction.

20. The DIB of claim 19, further comprising a locking feature configured to lock the connector in the mating orientation.

21. The DIB of claim 19, wherein the mating direction is substantially parallel to a surface of the DIB.

22. The DIB of claim 19, further comprising an interposer, and wherein the plurality of conductive leads are disposed on the interposer.

23. The DIB of claim 22, wherein the plurality of conductive leads comprise a plurality of pins.

24. A method of establishing a perpendicular blind mate connection, the method comprising:
inserting a connector comprising a plurality of cables coupled to a printed circuit board (PCB) into an adapter of a device interface board (DIB) in a mating direction; and
making electrical contact between a plurality of exposed contact pads of the PCB with a plurality of conductive leads of the DIB in a contact direction which is substantially perpendicular to the mating direction.

25. The method of claim 24, further comprising pushing the connector such that the connector is retained by a locking feature of the connector and/or the adapter.
